(19) United States
(12) Patent Application Publication
(10) Pub. No.: US 2006/0213648 A1
(43) Pub. Date: Sep. 28, 2006

(54) Method for manufacturing heat dissipation apparatus

(75) Inventors: Yency Chen, Taoyuan Hsien (TW); Hsin-Chang Tsai, Taoyuan Hsien (TW); Horng-Jou Wang, Taoyuan Hsien (TW); Chi-Feng Lin, Taoyuan Hsien (TW); Chin-Ming Chen, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/189,873

(22) Filed: Jul. 27, 2005

(30) Foreign Application Priority Data
Mar. 25, 2005 (TW) 94109210

(51) Int. Cl. H05K 7/20

(52) U.S. Cl. 165/104.33; 361/700

(57) ABSTRACT

A method for manufacturing a heat dissipation apparatus comprises the following steps: A substrate is provided. A pressure is exerted on the substrate by a roller mold to form a plurality of grooves on one surface of the substrate. A sealed chamber is formed out of the substrate so that the grooves are formed on an inner wall of the sealed chamber.

### BACKGROUND

The invention relates to a method for manufacturing a heat dissipation apparatus, and in particular, to a method for manufacturing a grooved vapor chamber.

When the number of electronic components per unit area of an electronic device increases, the amount of heat generated also increases greatly during operation. Thus, extra fans and heat dissipation fins are used to dissipate heat to maintain an effective operating temperature. Under small temperature differences and excluding an extra power supply, a great quantity of heat can be transferred through a heat pipe with a very small section area. To satisfy economic concerns, heat pipes are used to transfer heat in electronic heat dissipation products.

Typical heat pipes are composed of a chamber, a wick structure and a working fluid. The principle of heat pipe action is that the working fluid evaporates into vapor after the working fluid absorbs heat from the evaporator section of the chamber. Then, the vapor flows to the condenser section of the chamber, the vapor condenses into liquid state. Capillarity of the wick structure enables the working fluid to flow back to the evaporator section.

The vapor chamber is a kind of heat pipe. The vapor chamber is a sealed chamber by a top plate and a bottom plate. The inner wall of the top and bottom plates is formed with wick structures. Generally speaking, the vapor chamber comprises one of three wick structures: a meshed wick structure, a sintered wick structure, or a grooved wick structure.

Regarding the sintered wick structure in the prior art, sintered powder (such as copper powder) is sintered at the inner wall of the top and bottom plates of the vapor chamber at high temperature. Excessive heat during the sintering process, however, may easily cause the plates soften. Thus, the thickness of the plates must be increased so that the mechanical strength of the whole vapor chamber can be strengthened. This is an inadequate solution, however, as increasing the thickness of the plates not only increases both total material cost and the weight of the vapor chamber.

Regarding the meshed wick structure as disclosed in U.S. Pat. No. 6,293,333, the meshed wick structure with multiple flow passages is formed by metal mesh. Then, the meshed wick structure is attached to the inner wall of two plates (top and bottom plates) of the vapor chamber. Thus, the meshed wick structure provides more flow passages for the vapor chamber to achieve more efficient heat dissipation. However, the meshed wick structure must be absolutely attached to the inner wall of both plates, or heat conductive efficiency of the vapor chamber is affected. Manufacture of the wick structures is more complicated; consequently, costs in manufacture and material are increased.

Regarding the grooved wick structure as shown in FIG. 1A and FIG. 1B, FIG. 1A is a schematic view for showing a conventional process to manufacture a grooved wick structure on the inner wall of a vapor chamber. FIG. 1B depicts a finished vapor chamber with the grooved wick structure on its inner wall. As shown in FIG. 1A and FIG. 1B, the grooved wick structure of the conventional vapor chamber utilizes a mold 10 to press a predetermined dent 14 on the inner wall of the metal sheets 12 by machining. The obtainable minimum width of the grooved wick structure is, however, limited. When the number and the depth of the predetermined grooved wick structure of the metal sheets 12 increases, the impact needed in the manufacturing process increases. Thus, the design of mold 10 must change according to the number and the depth of the predetermined dents 14 in the metal sheets 12. Greater thrust is required to drive the mold 10 pressing the metal sheet 12 so that the number and the depth of the dents 14 are formed on the inner wall of the vapor chamber, however, manufacturing costs are also greatly increased. In addition, the predetermined width of gaps 16 are additionally reserved around the metal sheets 12 when the grooved wick structure is manufactured by pressing. The gaps 16 can ensure that the number of the grooved wick structures adequate when the metal plates are deformed in the pressing process. After pressing is complete, unnecessary gaps 16 around the sheet 12 are cut by cutting tools. Thus, material costs for manufacturing the vapor chamber are greatly increased

### SUMMARY

To solve the described problems, the invention provides a method for manufacturing a heat dissipation apparatus and a method for manufacturing a vapor chamber with grooves perfecting in irregular directions to improve heat dissipation efficiency. One-dimensional forming of the grooves substitutes for the conventional surface forming of the grooves. One-dimensional forming greatly decreases resistance when the grooves are formed so that a smaller machine tool can be used to manufacture the substrate of the vapor chamber with a large area. Thus, manufacturing costs are reduced and the productivity is increased. Furthermore, total weight of the vapor chamber is decreased and material consumption is reduced.

A method for manufacturing a heat dissipation apparatus is provided. An exemplary embodiment of a method for manufacturing a heat dissipation apparatus comprises the following steps. A substrate is provided. A pressure is exerted on the substrate by a roller mold to form a plurality of grooves on one surface of the substrate. The substrate is folded to form a chamber. One end of the chamber is sealed.

A working fluid is poured into the inner wall of the chamber. The chamber is vacuumed. The other end of the chamber is sealed to form a sealed chamber. The grooves are formed on the inner wall of the sealed chamber.

Another exemplary embodiment of a method for manufacturing a heat dissipation apparatus comprises the following steps. Two substrates are provided. A pressure is exerted on each substrate by a roller mold to form a plurality of grooves on surfaces of both substrates. Two substrates are connected to form a chamber by gluing, welding or fusing. One end of the chamber is sealed. A working fluid is poured into the inner wall of the chamber. The chamber is vacuumed. The other end of the chamber is sealed to form a sealed chamber. The grooves are formed on the inner wall of the sealed chamber.

### DESCRIPTION OF THE DRAWINGS

The invention can be more fully understood by reading the subsequent detailed description and examples with references made to the accompanying drawings, wherein:

FIG. 1A is a schematic view of a conventional method for manufacturing a grooved wick structure on an inner wall of a vapor chamber;

FIG. 1B is a schematic view of the grooved wick structure formed on the inner wall of the vapor chamber;

FIG. 2 is a sectional schematic view of an embodiment of a vapor chamber manufactured by a method for manufacturing a heat dissipation apparatus;

FIG. 3A is a schematic view of an embodiment of wick structure of the vapor chamber manufactured by a roller mold;

FIG. 3B is a schematic view of a formed wick structure of the vapor chamber;

FIGS. 4A-4C are schematic views of the roller molds used in manufacturing the vapor chamber; and

FIG. 5 is schematic view of wick structure of the vapor chamber manufactured by different roller molds.

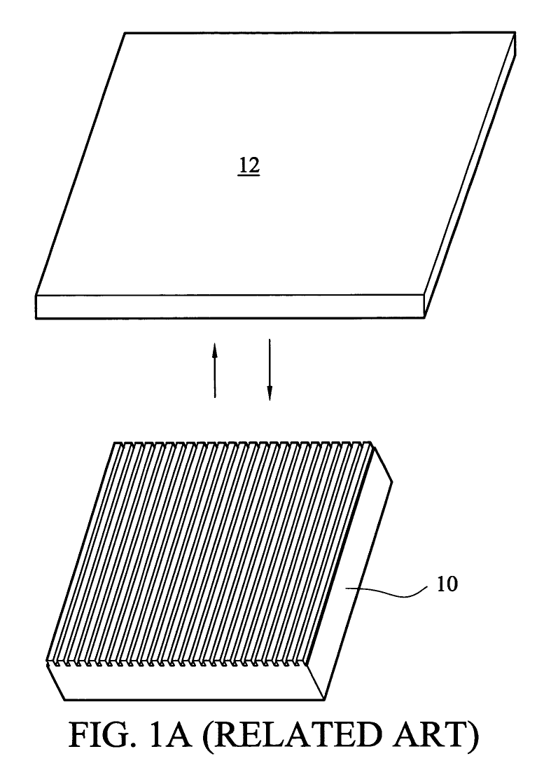

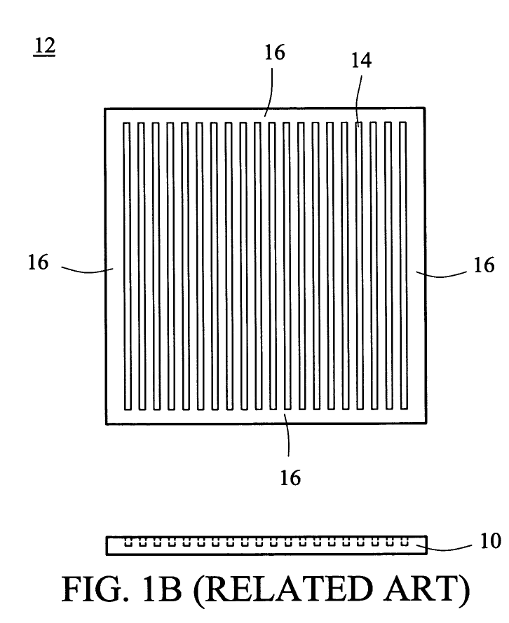

### DETAILED DESCRIPTION

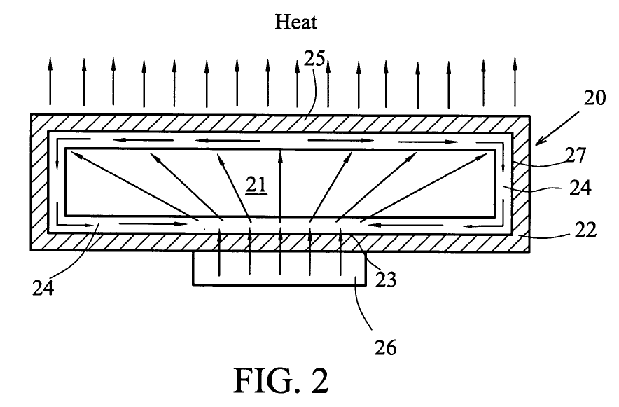

FIG. 2 is a sectional schematic view of an embodiment of a vapor chamber manufactured by a method for manufacturing a heat dissipation apparatus. As shown in FIG. 2, a vapor chamber 20 comprises a working fluid 24, a sealed chamber 21, an evaporator section 23, a condenser section 25, and a plurality of wick structures 27. The evaporator section 23, the condenser section 25, and the wick structures 27 are disposed on an inner wall 22 of the sealed chamber 21. The working fluid 24 continuously circulates in the sealed chamber 21 to achieve efficient heat dissipation.

The evaporator section 23 of the vapor chamber 20 is disposed opposite to a heating component 26. When heat generated from the heating component 26 is conducted to the evaporator section 23, the working fluid 24 absorbs heat so that the working fluid 24 evaporates into a gas phase of the working fluid 24. The gas phase of the working fluid 24 emits heat at the condenser section 25 and condenses into a liquid phase of the working fluid 24. The liquid phase of the working fluid 24 can flow back to the evaporator section 23 by capillarity of the wick structures 27.

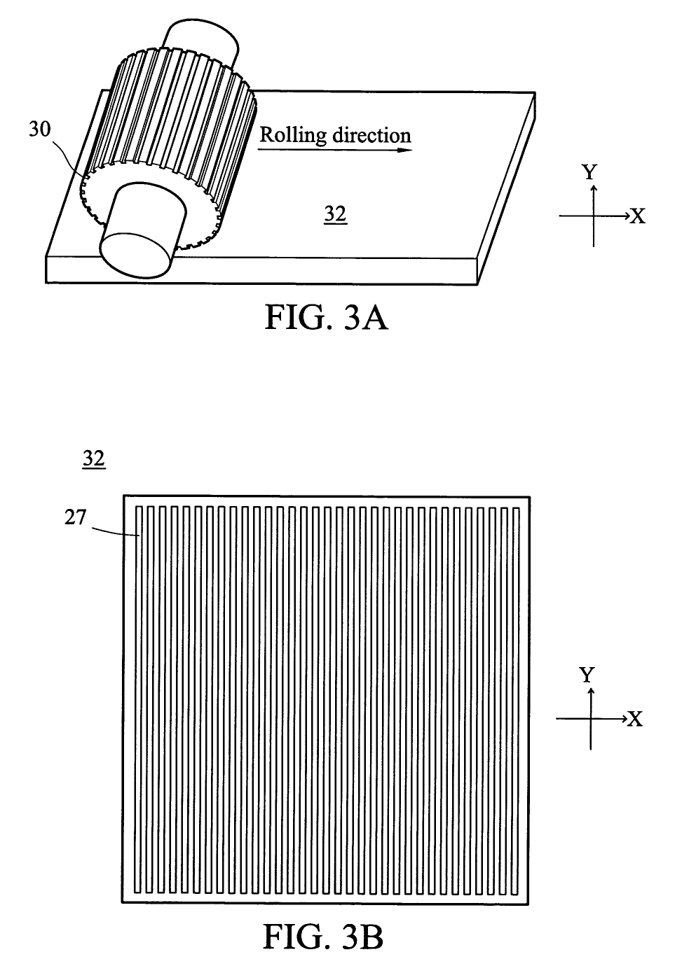

A method for manufacturing the grooved vapor chamber 20 is now described in detail. Referring to FIG. 3A and FIG. 3B, in cooperation with FIG. 2, FIG. 3A is a schematic view of an embodiment of a wick structure of the vapor chamber manufactured by a roller mold. FIG. 3B is a schematic view of a formed wick structure of the vapor chamber. As shown in FIG. 3A and FIG. 3B, to manufacture the vapor chamber 20, first, a substrate 32 is provided. The substrate 32 is selected from a group of aluminum, copper, titanium, molybdenum, or other metal materials with high thermal conductive coefficient. A roller mold 30 is then selected and the surface of which is designed according to the predetermined shape of the grooved wick structures 27 on the inner wall 22 of the vapor chamber 20. The roller mold 30 is further driven by machine tool and the substrate 32 is pressed along the rolling direction forming a plurality of grooves on the surface of the substrate 32. Thus, the vapor chamber 20 with the grooved wick structures 27 is complete.

Subsequently, the substrate 32 is curved, and two sides of the substrate 32 are connected to each other by welding or fusing to form a chamber and the grooved wick structures 27 on the inner wall 22 of the chamber. One end of the chamber is then sealed and the working fluid 24 is poured into the inner surface of the chamber. The working fluid 24 is selected from a group of inorganic compounds, water, alcohol, liquid metal, ketone, CFCs, and organic compounds. Last, the chamber is vacuumed and the other end of the chamber is sealed, and the manufacturing process of the grooved vapor chamber 20 is complete. Additionally, the evaporator section 23, the condenser section 25 and the grooved wick structures 27 are disposed on the inner wall 22 of the sealed chamber 21.

It should be noted that the arrangements of the grooved wick structures 27 on inner wall 22 of the sealed chamber 21 are not limited. Take FIG. 3A and FIG. 3B for example, when the roller mold 30 rolls along the direction of the X axis, the grooved wick structures 27 on the inner wall 22 of the sealed chamber 21 are arranged according to the Y axis in one dimension.

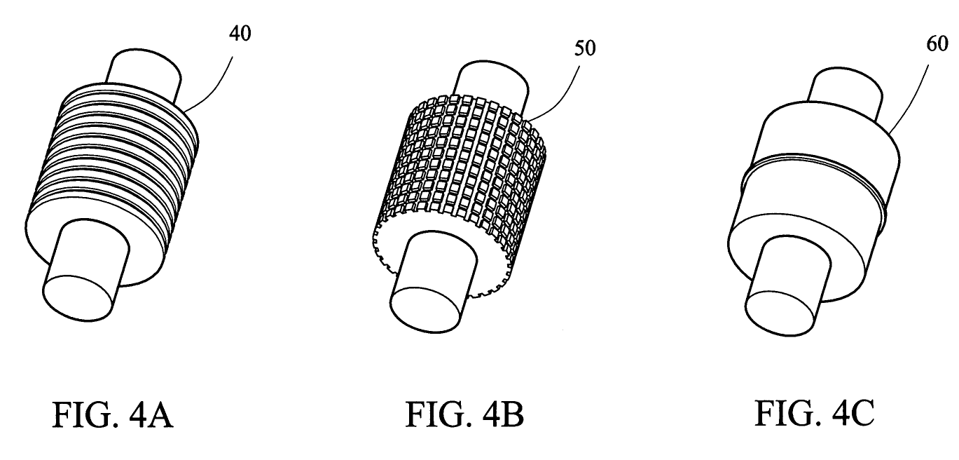

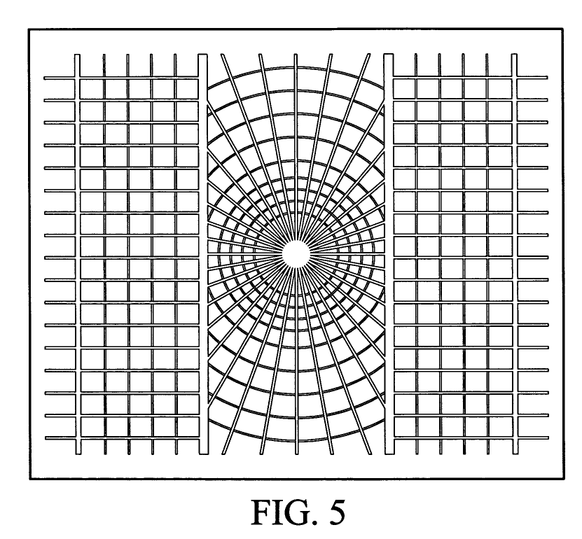

Referring to FIGS. 4A-4C and FIG. 5, FIGS. 4A-4C are schematic views of the roller molds used in manufacturing the vapor chamber. FIG. 5 is a schematic view of wick structure of the vapor chamber manufactured by different roller molds. As shown in FIG. 4A, when the roller mold 40 rolls along the direction of the X axis in FIG. 3A, the grooved wick structures 27 on the inner wall 22 of the sealed chamber 21 are arranged according to the Y axis in one dimension. As shown in FIG. 4B, when the roller mold 40 rolls along the direction of the X-axis in FIG. 3A, the grooved wick structures 27 on the inner wall 22 of the sealed chamber 21 are arranged in a mesh. As shown in FIG. 4C, when the roller mold 40 rolls along the direction of the X axis in FIG. 3A, the grooved wick structures 27 on the inner wall 22 of the sealed chamber 21 are arranged in a single groove. Subsequently, the single groove is taken as standard and the roller mold 60 is rotated a predetermined angle. Thus, a plurality of single grooves are repeatedly formed and the grooved wick structures 27 are formed in a radial arrangement.

It should be noted that the surface pattern of the roller mold is not limited to the described design. For example, the surface pattern of the roller mold can be designed to a non-linear shaped to manufacture a plurality of concentric-circled grooves. Additionally, the radial grooves manufactured by the roller mold 60 are combined, and the grooved wick structures 27 are radially arranged, arranged in a concentric circle, or two arrangements are arranged in staggered manner. In addition, the meshed grooves manufactured by the roller mold 50 are also combined, and the grooved wick structures 27 are radially, arranged in a plurality of the concentric circles, arranged in mesh, or two arrangements staggered, as shown in FIG. 5.

Furthermore, the vapor chamber is not limited to curving a substrate to form a chamber, and a plurality of substrates can be used to form the chamber. When at least a substrate of the plurality of the substrates has been formed, the substrates are connected by gluing, welding or fusing. Accordingly, the grooved wick structures are formed on the inner wall of the chamber and communicate with each other after connecting the substrates. Moreover, the method by using a plurality of substrates is the same with that by using one substrate so that not to say more then what is needed.

The invention provides a method for manufacturing a heat dissipation apparatus and a method for manufacturing a vapor chamber with grooves perfecting in irregular directions. Furthermore, one-dimensional forming of the grooves substitutes for the conventional surface forming of the grooves. When the number of the predetermined grooved wick structures on the inner wall of the vapor chamber is increased or the depth of the predetermined grooved wick structure is increased, only the number of surface grooves of the roller mold is increased and a machine tool with the smaller tonnage is used. The gaps need not be reserved around the substrate, thus, material consumption is reduced. Thus, manufacturing costs decreased and productivity is increased.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for manufacturing a heat dissipation apparatus, comprising the steps of:
providing a substrate;
exerting a pressure on the substrate by a roller mold to form a plurality of grooves on a surface of the substrate; and
forming a sealed chamber out of the substrate so that the grooves are formed on an inner wall of the sealed chamber.

2. The method as claimed in claim 1, wherein the grooves are arranged in one dimension.

3. The method as claimed in claim 1, wherein the grooves are arranged in different dimensions and in staggered manner.

4. The method as claimed in claim 1, wherein the grooves are radially arranged, arranged in a concentric circle, or two arrangements are arranged in staggered manner.

5. The method as claimed in claim 1, wherein the groves are radially arranged, arranged in a concentric circle, arranged in a mesh, or these arrangements cooperate with each other.

6. The method as claimed in claim 1, wherein the substrate is selected from a group of aluminum, copper, titanium, molybdenum, or other metal materials with high thermal conductive coefficient.

7. The method as claimed in claim 1, wherein the step of forming the sealed chamber out of the substrate comprises:
folding the substrate to form a chamber;
sealing one end of the chamber;
pouring a working fluid in the chamber; and
sealing the other end of the chamber.

8. The method as claimed in claim 7, wherein two sides of the substrate are connected to form the chamber by welding, fusing, or gluing.

9. The method as claimed in claim 7, further comprising a step of vacuuming the chamber before sealing the other end of the chamber.

10. The method as claimed in claim 7, wherein the working fluid is selected from a group of inorganic compounds, water, alcohol, liquid metal, ketone, CFCs, and organic compounds.

11. A method for manufacturing a heat dissipation apparatus, comprising the steps of:
providing a plurality of substrates;
exerting a pressure on at least one substrate of the substrates by a roller mold to form a plurality of the grooves on a surface of the at least one substrate; and
forming a sealed chamber out of the plurality of substrates so that the grooves are formed on an inner wall of the sealed chamber.

12. The method as claimed in claim 11, wherein the grooves of the at least one substrate are arranged in one dimension, and the grooves are connected to each other correspondingly.

13. The method as claimed in claim 11, wherein the grooves of the at least one substrate are arranged in different dimensions and in a staggered manner.

14. The method as claimed in claim 11, wherein the grooves of the at least one substrate are radially arranged, arranged in concentric circle, or two arrangements are arranged in staggered manner.

15. The method as claimed in claim 11, wherein the groves of the at least one substrate are radially arranged, arranged in a concentric circle, arranged in a mesh, or these arrangements cooperate with each other.

16. The method as claimed in claim 11, wherein each substrate is selected from a group of aluminum, copper, titanium, molybdenum, or other metal materials with high thermal conductive coefficient.

17. The method as claimed in claim 11, wherein the step of forming the sealed chamber from the substrates comprises:
connecting the plurality of substrates to form a chamber;
sealing one end of the chamber;
pouring a working fluid in the chamber; and
sealing the other end of the chamber.

18. The method as claimed in claim 17, further comprising a step of vacuuming the chamber before sealing other end of the chamber.

19. The method as claimed in claim 17, wherein the plurality of substrates are connected to form the chamber by welding, fusing, or gluing.

20. The method as claimed in claim 17, wherein the working fluid is selected from a group of inorganic compounds, water, alcohol, liquid metal, ketone, CFCs, and organic compounds.
